(19) United States
(12) Patent Application Publication
(10) Pub. No.: US 2013/0106712 A1
(43) Pub. Date: May 2, 2013

(54) METHOD OF REDUCING GLARE FROM INNER LAYERS OF A DISPLAY AND TOUCH SENSOR STACK

(71) Applicants: William J. Cummings, Clinton, WA (US); Marek Mienko, San Jose, CA (US); Hamid Tavakoli, San Jose, CA (US)

(72) Inventors: William J. Cummings, Clinton, WA (US); Marek Mienko, San Jose, CA (US); Hamid Tavakoli, San Jose, CA (US)

(73) Assignee: QUALCOMM MEMS Technologies, Inc., San Diego, CA (US)

(21) Appl. No.: 13/286,914

(22) Filed: Nov. 1, 2011

(51) Int. Cl. G06F 3/041; H05K 13/00

(52) U.S. Cl. 345/173; 29/592.1

(57) ABSTRACT

This disclosure provides systems, methods and apparatus related to touchscreens where glare from locations behind a front surface are reduced. In certain implementations, a bulk diffuser can be provided at one or more locations between a cover plate and a touch panel of a touchscreen or between the touchscreen and a display device. Various properties associated with the bulk diffuser, including a haze level and thickness, can be selected so as to yield a desired glare reduction in touchscreen devices that utilize different displays. Such displays can include an interferometric modulator-based display, as well as other types of displays.

### TECHNICAL FIELD

This disclosure relates to display devices including electromechanical systems, and more particularly, to touchscreen devices having reduced internal glare.

### DESCRIPTION OF THE RELATED TECHNOLOGY

Electromechanical systems (EMS) include devices having electrical and mechanical elements, actuators, transducers, sensors, optical components (such as mirrors and optical film layers) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

In some display devices having a number of transparent layers, reflections can occur whenever light attempts to travel through an interface between different layers. When such a light originates from an external location, such reflections at different interfaces can result in undesirable glare originating from locations behind the front surface of the device.

### SUMMARY

The systems, methods and devices of the disclosure each have several innovative aspects, no single one of which is solely responsible for the desirable attributes disclosed herein.

One innovative aspect of the subject matter described in this disclosure can be implemented in a display apparatus that includes a front cover, a touch panel disposed rearward of the front cover and having front and rear surfaces. The apparatus further includes a display array rearward of the touch panel. The apparatus further includes at least one bulk diffuser disposed rearward of the front cover so as to reduce glare resulting from substantially specular reflection from at least one of the front and rear surfaces of the touch panel.

In some implementations, the bulk diffuser can include a layer of diffusive adhesive. In some implementations, the at least one bulk diffuser can include a first diffuser layer disposed between the front cover and the touch panel. The apparatus can further include a second diffuser layer disposed between the touch panel and the display array.

In some implementations, the display apparatus can further include a transparent adhesive disposed between the front cover and the touch panel. In some implementations, the display array can include an interferometric modulator array.

In some implementations, at least one of the surfaces of the touch panel can include a diffusive surface. The touch panel diffusive surface can include a roughened surface having an effective refractive index, and the refractive index difference between the roughened surface and a medium disposed next to the diffusive surface can be greater than or equal to about 0.01. The medium can include materials such air, a bonding material, or ITO (indium tin oxide).

In some implementations, the at least one bulk diffuser can include a plurality of layers, with each layer having a haze characteristic that decreases as a function of the layer's distance from the display array.

In some implementations, the display apparatus can further include a processor that is configured to communicate with the display array, and configured to process image data. The display apparatus can further include a memory device that is configured to communicate with the processor.

In some implementations, the display apparatus can further include a driver circuit configured to send at least one signal to the display array, and a controller configured to send at least a portion of the image data to the driver circuit. In some implementations, the display apparatus can further include an image source module configured to send the image data to the processor and including at least one of a receiver, transceiver, and transmitter. In some implementations, the display apparatus can further include an input device coupled to the touch panel and configured to receive input data and to communicate the input data to the processor.

Another innovative aspect of the subject matter described in this disclosure can be implemented in a touchscreen device having an external surface. The device includes a display and a touch sensor. The device further includes at least one bulk diffuser disposed relative to the touch sensor so as to reduce glare from one or more internal surfaces of the touchscreen device.

In some implementations, the touchscreen device can further include a cover plate disposed such that the touch sensor is between the cover plate and the display, with one surface of the cover plate defining the external surface of the touchscreen device. In some implementations, the at least one bulk diffuser can be disposed between the cover plate and the touch sensor or can be disposed between the touch sensor and the display.

Yet another innovative aspect of the subject matter described in this disclosure can be implemented in a method for fabricating a display. The method includes providing a display array, and providing a touch panel having front and rear surfaces in front of the display array. The method further includes forming at least one bulk diffuser at one or more sides of the front and rear surfaces of the touch panel. The method further includes disposing a front cover in front of the touch panel.

In some implementations, the at least one bulk diffuser can be formed so as to be in direct contact with the front surface of the touch panel or in direct contact with the rear surface of the touch panel. In some implementations, the method can further include forming at least one non-diffusive layer at one or more sides of the front and rear surfaces of the touch panel. Such a non-diffusive layer can be formed so as to be positioned between the front or rear surface of the touch panel and the at least one bulk diffuser.

Yet another innovative aspect of the subject matter described in this disclosure can be implemented in a method for fabricating a touchscreen device. The method includes providing a display, and providing a touch sensor. The method further includes providing a cover plate disposed such that the touch sensor is between the cover plate and the display. The method further includes forming at least one bulk diffuser between the display and the display so as to reduce glare from one or more internal surfaces of the touchscreen device.

Yet another innovative aspect of the subject matter described in this disclosure can be implemented in an apparatus having a display device configured to display an image by providing signals to selected locations of the display device. The apparatus further includes a touch panel configured to receive user inputs. The apparatus further includes a front cover configured to protect the touch panel. The apparatus further includes means for reducing glare resulting from specular reflection from at least one surface below the front cover.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 shows an example of specular reflection(s) of incident light at one or more surfaces behind an external surface of a touchscreen assembly to yield an undesirable glare.

FIG. 10 shows an example of a touchscreen assembly having one or more diffusers so as to reduce glare from locations behind an external surface of the touchscreen assembly.

FIGS. 11A and 11B show examples of cross-sectional schematic illustrations of a touchscreen assembly having a front cover, a touch panel with one or more transparent conductive layers, and a bulk diffuser therebetween.

FIGS. 12A and 12B show examples of cross-sectional schematic illustrations of a touchscreen assembly having a front cover, a touch panel with one or more transparent conductive layers, and disposed therebetween a bulk diffuser and a transparent adhesive.

FIGS. 13A and 13B show examples of cross-sectional schematic illustrations of a touchscreen assembly having a front cover, a touch panel, a display device, and disposed between the touch panel and the display a bulk diffuser.

FIGS. 14A and 14B show examples of cross-sectional schematic illustrations of a touchscreen assembly having a front cover, a touch panel, a display device, and disposed between the touch panel and the display a bulk diffuser and a transparent adhesive.

FIGS. 15A and 15B show examples of cross-sectional schematic illustrations of a touchscreen assembly having a number of interface surfaces behind the front surface of a front cover, where one or more of such interface surfaces can be configured as a diffusive surface having a desired diffusion property.

FIG. 16 shows a process that can be implemented to fabricate a display device having a bulk diffuser for reducing glare from one or more surfaces behind the front surface of a touchscreen device.

FIG. 17 shows a process that can be implemented to fabricate a touchscreen device having a bulk diffuser for reducing glare from one or more surfaces behind the front surface of a cover plate.

FIG. 18 shows a process that can be implemented to fabricate a touchscreen display device having a bulk diffuser for reducing glare from one or more surfaces behind the front surface of a cover plate of the touchscreen.

FIG. 19 shows a process that can be implemented to fabricate a touchscreen device having one or more diffusive surfaces.

FIGS. 20A and 20B show examples of system block diagrams illustrating a display device that includes a plurality of interferometric modulators.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (e.g., video) or stationary (e.g., still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (e.g., display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

This disclosure includes various examples of devices and fabrication methods relating to touchscreens configured to reduce undesirable glare from locations behind the front surface of the touchscreen (e.g., a viewable surface of the touchscreen). Such glare can result from one or numerous undesired specular reflections of light rays at different interfaces between one or more layers associated with a touchscreen. In some implementations, one or more bulk diffuser layers can be provided at different locations of the touchscreen to diffuse such specular reflections and thereby desirably reduce the glare as seen by the user.

Particular implementations of the subject matter described in this disclosure can be implemented to realize one or more of the following potential advantages. For example, one or more features of this disclosure can be implemented to control glare in touchscreen devices in situations where anti-reflection and/or anti-glare coatings or treatments are typically difficult to implement. Such a reduced glare can increase apparent display contrast and the effectiveness of using a device with a touchscreen in front of the display.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity. One way of changing the optical resonant cavity is by changing the position of the reflector.

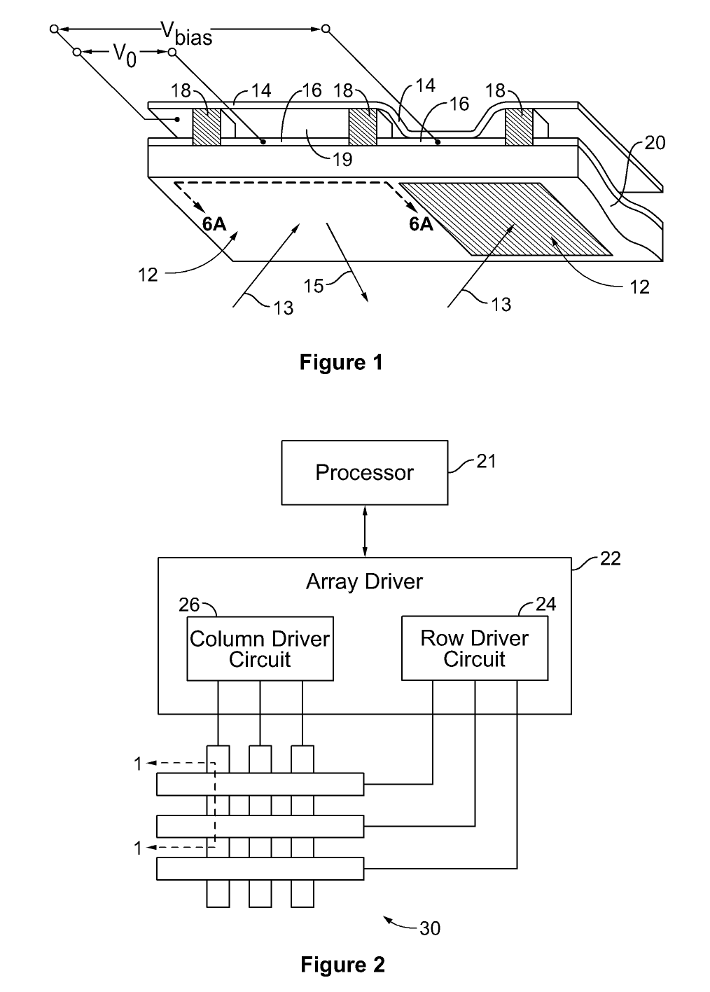

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, absorbing and/or destructively interfering light within the visible range. In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, such as chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and electrical conductor, while different, electrically more conductive layers or portions (e.g., of the optical stack 16 or of other structures of the IMOD) can serve to bus signals between IMOD pixels. The optical stack 16 also can include one or more insulating or dielectric layers covering one or more conductive layers or an electrically conductive/optically absorptive layer.

In some implementations, the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than <10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, a voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example, a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

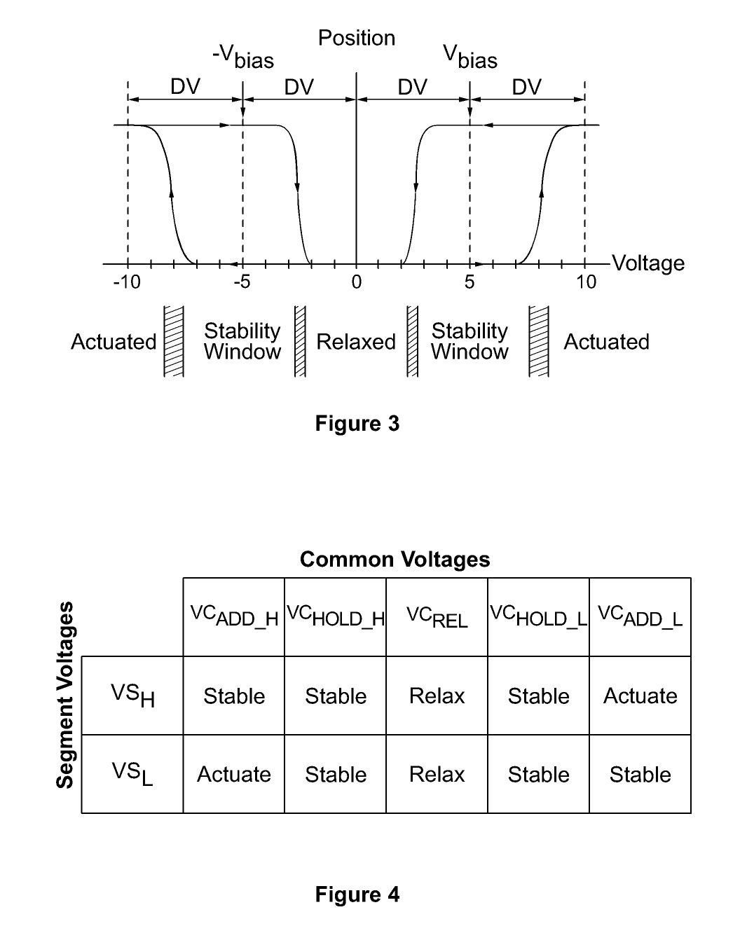

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may use, in one example implementation, about a 10-volt potential difference to cause the movable reflective layer, or mirror, to change from the relaxed state to the actuated state. When the voltage is reduced from that value, the movable reflective layer maintains its state as the voltage drops back below, in this example, 10 volts, however, the movable reflective layer does not relax completely until the voltage drops below 2 volts. Thus, a range of voltage, approximately 3 to 7 volts, in this example, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about, in this example, 10 volts, and pixels that are to be relaxed are exposed to a voltage difference of near zero volts. After addressing, the pixels can be exposed to a steady state or bias voltage difference of approximately 5 volts in this example, such that they remain in the previous strobing state. In this example, after being addressed, each pixel sees a potential difference within the “stability window” of about 3-7 volts. This hysteresis property feature enables the pixel design, such as that illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be understood by one having ordinary skill in the art, the “segment” voltages can be applied to either the column electrodes or the row electrodes, and the “common” voltages can be applied to the other of the column electrodes or the row electrodes.

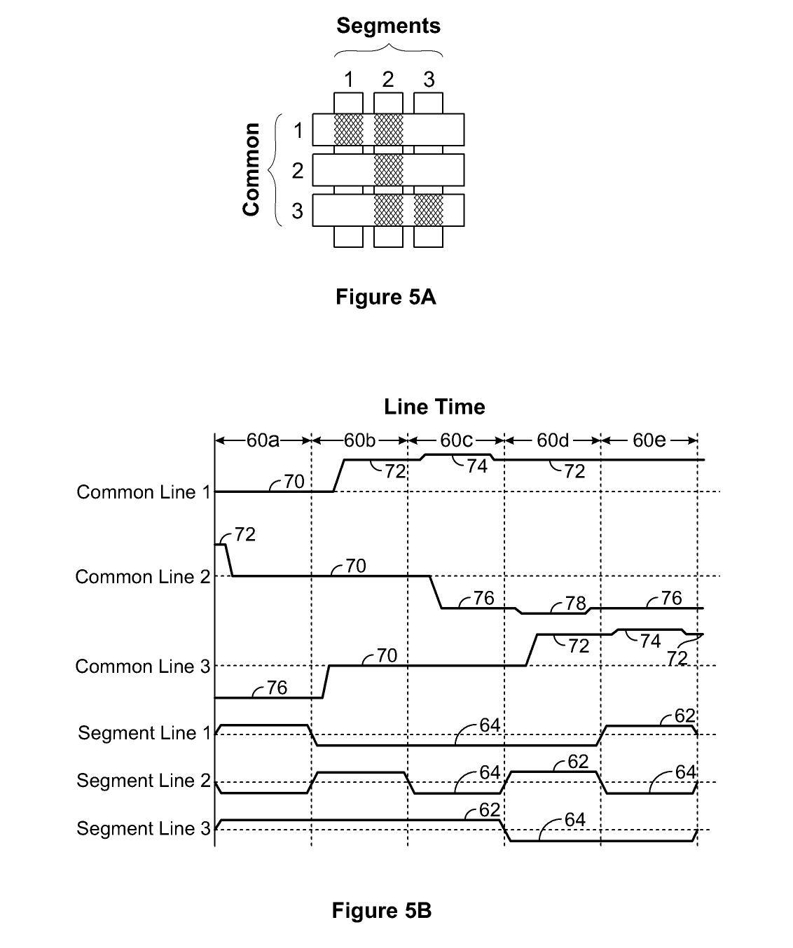

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator pixels (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators from time to time. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to a 3×3 array, similar to the array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, for example, a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}−relax and VC_{HOLD}_{_{—}}_{L}−stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

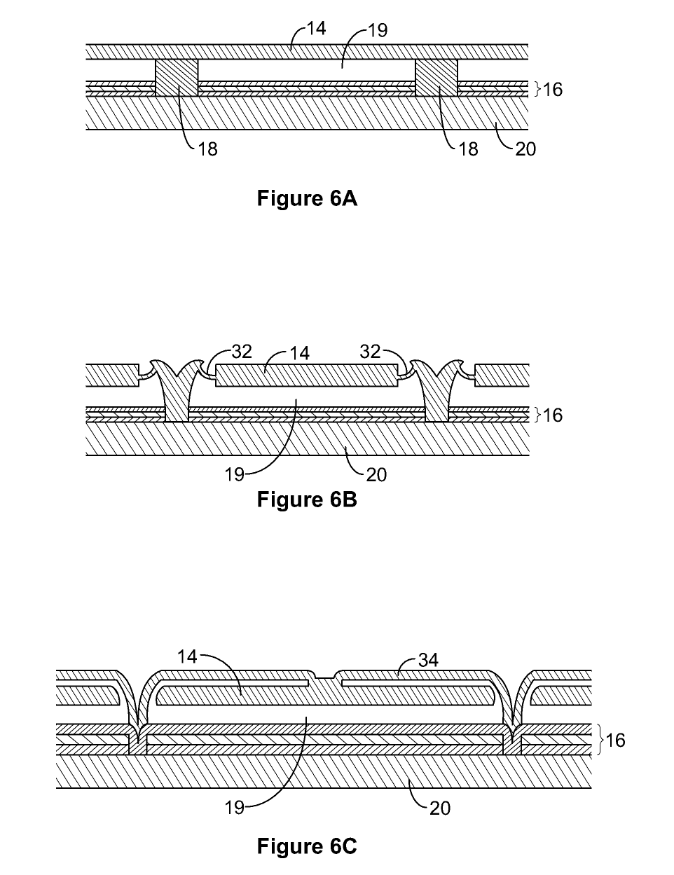

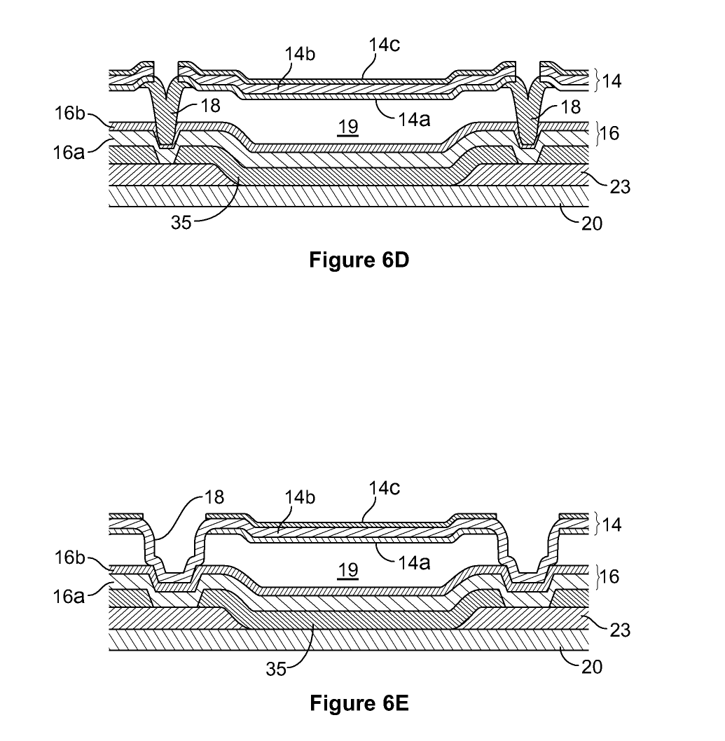

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, for example, an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (such as between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer. In some implementations, the optical absorber 16a is an order of magnitude (ten times or more) thinner than the movable reflective layer 14. In some implementations, optical absorber 16a is thinner than reflective sub-layer 14a.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, for example, patterning.

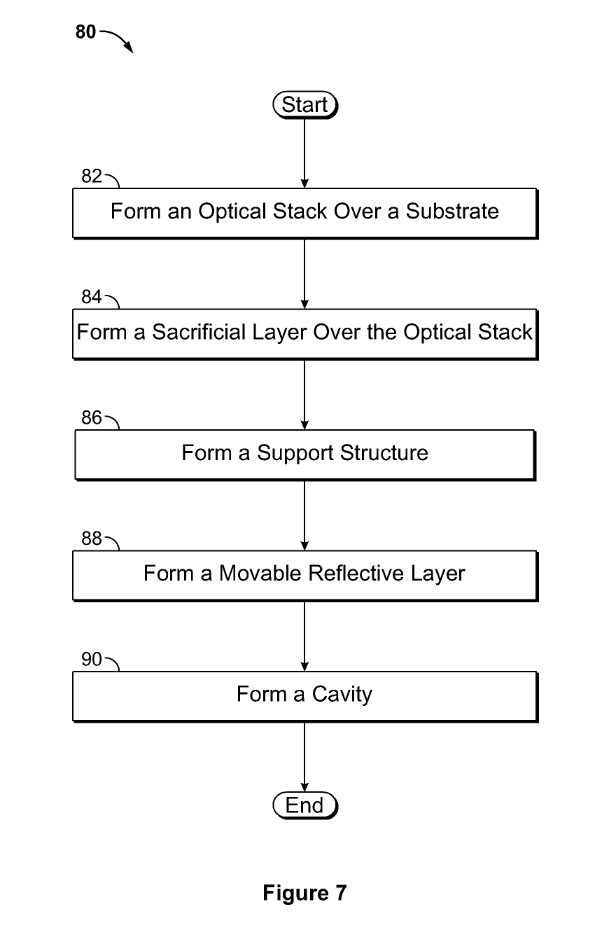

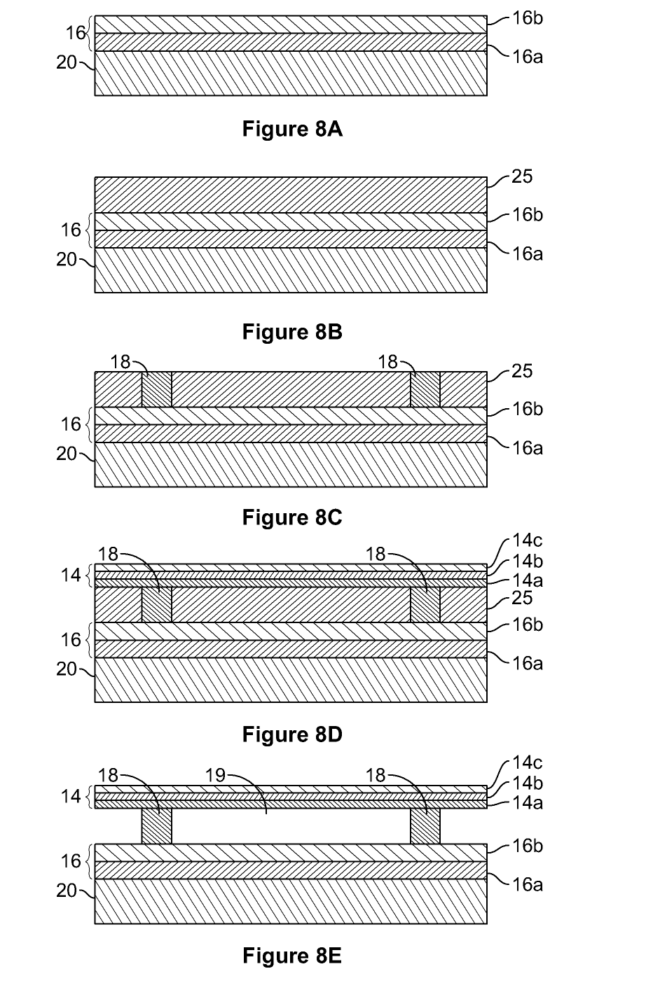

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture an electromechanical systems device such as interferometric modulators of the general type illustrated in FIGS. 1 and 6. The manufacture of an electromechanical systems device can also include other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, such as cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and electrically conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display. It is noted that FIGS. 8A-8E may not be drawn to scale. For example, in some implementations, one of the sub-layers of the optical stack, the optically absorptive layer, may be very thin, although sub-layers 16a, 16b are shown somewhat thick in FIGS. 8A-8E.

The process 80 continues at block 84 with the formation of a sacrificial layer 25 over the optical stack 16. The sacrificial layer 25 is later removed (see block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (a-Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, which includes many different techniques, such as sputtering), plasma-enhanced chemical vapor deposition (PECVD), thermal chemical vapor deposition (thermal CVD), or spin-coating.

The process 80 continues at block 86 with the formation of a support structure such as post 18, illustrated in FIGS. 1, 6 and 8C. The formation of the post 18 may include patterning the sacrificial layer 25 to form a support structure aperture, then depositing a material (such as a polymer or an inorganic material such as silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps including, for example, reflective layer (such as aluminum, aluminum alloy, or other reflective layer) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, such as cavity 19 illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, by exposing the sacrificial layer 25 to a gaseous or vaporous etchant, such as vapors derived from solid XeF₂, for a period of time that is effective to remove the desired amount of material. The sacrificial material is typically selectively removed relative to the structures surrounding the cavity 19. Other etching methods, such as wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

In some implementations, a display can be combined with an input device so as to yield an interface device that allows a user to view an image formed on the display and provide inputs using the interface device. Such an interface device is commonly referred to as a touchscreen. A touchscreen can be capable of sensing positions of an input touch by an object such as a finger tip or a stylus. Such position sensing of the input touch can be achieved via a number of techniques, including, for example, resistive sensing, capacitive sensing, surface acoustic wave sensing, and optical sensing. Such touchscreens are used in many electronic devices such as portable computing and/or communication devices to provide user interface functionalities.

As described herein, the term “touchscreen” (or “touch screen”) can include configurations where a user's inputs may or may not involve physical contact between a touching object (such as a fingertip or a stylus) and a surface of a screen. As described herein, location of the “touching” object can be sensed with or without such physical contact, for example, when the location of the touching object is in proximity to the surface of a screen. Another example configuration can include an additional functional or passivation layer positioned in front of a touch screen, so that a user touches the additional layer but not the touchscreen itself.

In some implementations, a display coupled with a touchscreen can include an interferometric modulator-based display having one or more features as described herein. In other implementations, such a display can be an LCD device, a transreflective display device, an electronic ink display device, a plasma display device, an electrochromism display device, an electro wetting display device, or an electro luminescence display device. Other types of displays can also be used.

As used herein, relative terms, such as “front,” “rear,” “upper” or “lower” (and similar terms) may be used to describe one element's relationship to another element. It will be understood that relative terms are intended to encompass different orientations of a device. For example, if a device in one of the figures is turned over, an element described as being on the “lower” side of another element can then be oriented on the “upper” side of the other element. The example term “lower,” can therefore, encompasses both an orientation of “lower” and “upper,” depending of the particular orientation of the figure.

Interface devices having a touchscreen can include a transparent cover plate (sometimes referred to as a cover lens) having a front surface facing a user and a rear surface opposite the front surface. In some implementations, the front surface is closer to the surface configured to receive the touch input than the rear surface. In some implementations, the front surface itself is configured to receive the touch input. Such a cover plate can function as a protective layer for a touchscreen and a display device, while allowing the sensing functionality of the touch panel and viewing of the display device. Such an interface device can suffer from glare resulting from specular reflection of external light (for example, ambient light) at the front surface of the cover plate and various interface surfaces rearward of the front surface. While the glare resulting from the front surface of an interface device can be addressed by anti-reflective (AR) and/or anti-glare (AG) coating(s), glare resulting from light transmitted through the front surface of the cover plate and reflecting from one or more surfaces within the interface device can be difficult to control.

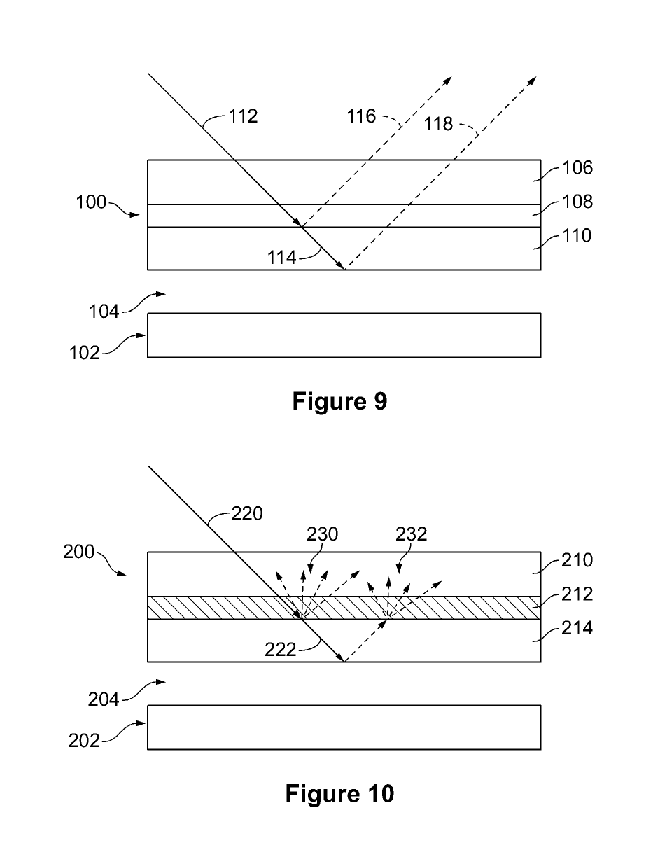

FIG. 9 shows an example of such specular reflections of incident light 112 at one or more surfaces behind an external surface of a touchscreen assembly 100 to yield an undesirable glare. For example, suppose that the touchscreen assembly 100 includes a transparent cover plate 106 and a touch panel 110 coupled together via a transparent coupling component 108 such as adhesive. The touchscreen assembly 100 is further shown to be disposed in front of a display device 102, and there can be a gap 104 therebetween. In some implementations, the gap 104 includes an air gap. The gap can include an adhesive layer disposed therein (not shown in FIG. 9).

In FIG. 9, a light ray 112 from an external source (not shown) is depicted as being incident on the touchscreen assembly 100 and entering the cover plate 106. For the purpose of description, reflection of the incident ray 112 at the front surface of the cover plate 106 and any AR/AG effect which may or may not exist are not shown. An example reflection of the incident ray 112 at the front portion of the touch panel 110 yields a reflected ray 116 that exits the touchscreen assembly 100. In another example, the transmitted portion of the incident ray 112 is depicted as travelling through the touch panel 110 (as ray 114) and being reflected at the rear portion of the touch panel 110 to yield another reflected ray 118 that also exits the touchscreen assembly 100. In some situations, the example reflections that yield the rays 116 and 118 can be specular. Thus, if a user's viewing orientation is at or near the direction of the reflected rays 116 and 118, a glare (from the external light source) can degrade the user's viewing enjoyment.

FIG. 10 shows that, in some implementations, a touchscreen assembly 200 can include one or more diffusers configured to reduce glare from locations behind the front surface of the touchscreen assembly. The touchscreen assembly 200 is shown to include a transparent cover plate 210 and a touch panel 214 coupled together with a diffusion layer, e.g., bulk diffuser 212, disposed between the cover plate 210 and the touch panel 214. The touch screen assembly 200 is shown to be disposed in front of a display device 202, and there may be a gap 204 (e.g., air gap) therebetween. The gap may or may not be occupied by, for example, an adhesive layer (not shown in FIG. 10).

In FIG. 10, a light ray 220 from an external source (not shown) is depicted as being incident on the touchscreen assembly 200 and entering the cover plate 210. For the clarity of FIG. 10 and this disclosure, reflections of the incident ray 220 at the front surface of the cover plate 210 and any AR/AG effect which may or may not exist are not shown. An example reflection of the incident ray 220 at the front portion of the touch panel 214 is depicted as being diffused by the bulk diffuser 212 so as to yield diffused light rays 230 propagating in different directions. In another example, the transmitted portion of the incident ray 220 is depicted as travelling through the touch panel 214 (as ray 222) and being reflected at the rear portion of the touch panel 214 to yield a reflected ray that travels back through the touch panel and is diffused by the bulk diffuser 212 so as to yield diffused light rays 232 which can propagate in different directions. Thus, even if a user's viewing orientation is at or near the direction of what would be a specular reflection of the incident ray 220, the reflected rays 230 and 232 are diffused into different directions such that a glare can be reduced. Such glare-reducing functionality can be implemented in a number of ways; and non-limiting examples are described herein.

A capacitive position sensing touchscreen configuration is used in some examples herein when describing various glare-reduction features. However, it will be understood that one or more glare-reduction features described herein can be implemented in various touchscreen devices having other types of input position sensing functionalities.

As described herein, a bulk diffuser can include a medium through which light can travel and undergo one or more significant direction changes. Such direction changes can occur due to scattering of light by particles or features within the medium; and the direction changes may or may not be random. Further, such a bulk diffuser may or may not involve attenuation of light intensity by, for example, absorption.

A bulk diffuser can be implemented in a number of ways. For example, a diffusion layer having a certain thickness can include particles and/or features distributed therein and/or on the surfaces of the diffusion layer. The thickness and an average density of such light scattering particles and/or features can be selected to provide desired light transmitting and diffusing properties.

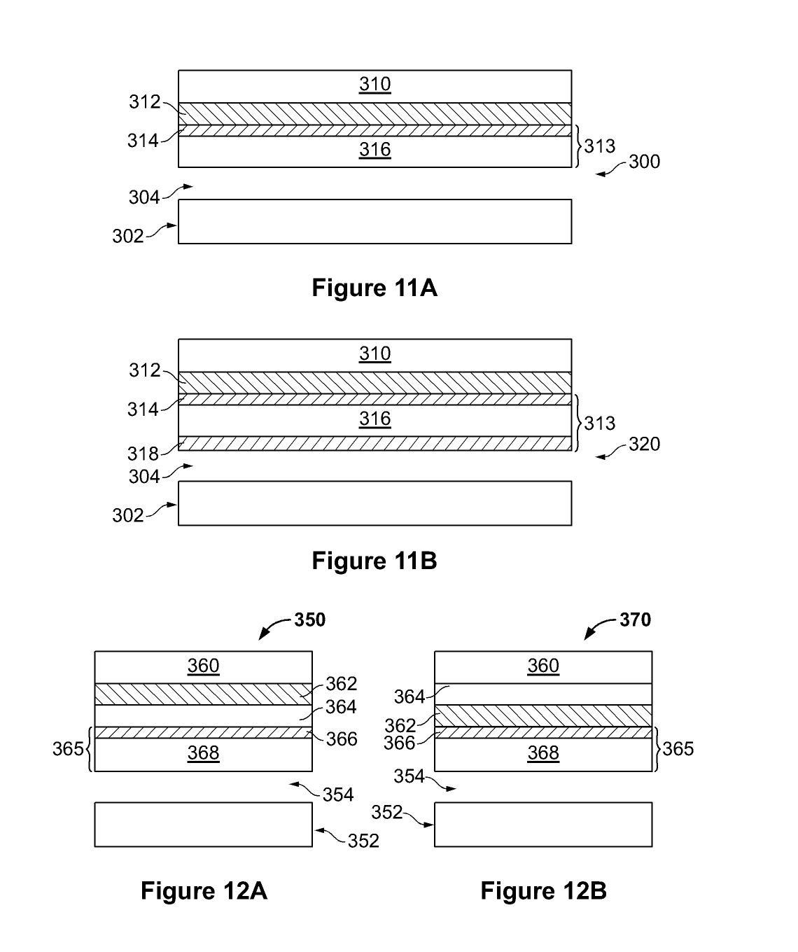

In some implementations, such a diffusion layer can be a layer that is provided between, for example, the touch panel 214 and the cover plate 210 during assembly. The diffusion layer can be an adhesive layer. In some implementations, a diffusion layer can be part of a layer (for example, a diffusive layer having a thickness) that has already been formed on one side of a transparent layer (for example, the touch panel or the cover plate) prior to assembly. Various combinations of the foregoing examples, as well as other configurations, are also possible. More specific example configurations that can be implemented are described herein in reference to FIGS. 11-19.

In some implementations of the separate diffusion layer (such as adhesive layer), the thickness can be selected to be at least about 1 μm. In some implementations, the separate diffusion layer can have a thickness between about 1 μm to about 250 μm; about 10 μm to about 100 μm; or about 25 μm to about 80 μm. In some implementations of the separate diffusion layer (such as adhesive layer), can be configured to have an appropriate particle density (such as average particle density) to yield a desired bulk diffusion and/or haze functionality as described herein.

FIGS. 11A and 11B show examples of cross-sectional schematic illustrations of touchscreen assemblies (300 in FIG. 11A, 320 in FIG. 11B) having a front cover plate 310 and a touch panel 313. In FIG. 11A, the touch panel 313 includes one transparent conductive layer 314 and a transparent insulator 316. In FIG. 11B, the touch panel includes two transparent conductive layers 314 and 318, and a transparent insulator 316 disposed between the conductive layers 314 and 318. In some implementations, the front cover plate 310 can be formed from materials such as glass. In some implementations, the insulator 316 can be formed from materials such as glass. In some implementations, each of the conductive layers 314 and 318 can be formed from materials such as indium tin oxide (ITO) and configured to provide capacitive position sensing functionalities. The cross-sectional depictions of FIGS. 11A and 11B, hatch marks for conductive layers 314 and 318 are provided to distinguish various layers in an assembly, and not to indicate any lateral orientations of such conductive layers in the context of position sensing functionalities.

In the example of FIG. 11A, the conductive layer 314 of the touch panel 31 is disposed on the front side of the insulator 316, in other words, on a side of the insulator 316 facing the front cover plate 310 whose front surface is intended to be touched by an object such as a finger. In the example of FIG. 11B, the conductive layers 314 and 318 of the touch panel 313 are disposed on the front and rear sides of the insulator 316. In the example implementations illustrated in FIGS. 11A and 11B, the touch panels 313 are depicted as being in front of a display device 302, with a gap 304 therebetween.

FIGS. 11A and 11B show that in some implementations, a bulk diffuser 312 can be disposed between the touch panel 313 and the cover plate 310. FIG. 11B illustrates diffuser 312 in front of the touch panel 313, but that in some implementations, another diffuser may be disposed between touchscreen assembly 320 and the display 302. In some implementations, the diffuser 312 can be a bulk diffuser. In some implementations, the diffuser 312 can be, at least in part, an adhesive that bonds the touch panel 313 with the cover plate 310. Such a bonded assembly can then be attached in front of the display device 302 by a bonding technique or some other technique that yields, for example, an air gap.

In some implementations, the front and rear surfaces of the cover plate 310 can be provided with AR and/or AG coatings. Such coatings for the rear surface of the cover plate 310 can be applied, for example, before bonding of the cover plate 310 with the touch panel 313. Thus, in the example configurations shown in FIGS. 11A and 11B, the diffuser 312 being positioned rearward of the cover plate 310 but in front of the touch panel 313 and the display device 302 can allow diffusion of undesired reflections from locations rearward of the cover plate 310. Such reflections can include those from the front and rear surfaces of the transparent insulator 316, as well as reflections occurring from the display device 302.

In the examples described in reference to FIGS. 11A and 11B, substantially the entire diffuser 312 can be an adhesive bulk diffuser. In some implementations, however, to bond the cover plate 310 with the touch panel 313, one or more additional non-diffusing adhesive layers can also be used.

In some implementations, it may be desirable to provide at least some separation distance between a cover plate and a touch panel; and at the same time, it may not be desirable to fill such a gap with a bulk diffuser such as an adhesive having diffusion properties. For example, the thickness of the diffusing adhesive may result in too much absorption and/or too much diffusion. In such situations, it may be desirable to provide a bulk diffuser to yield selected optical properties; and fill the remainder of the gap with a transparent material such as a transparent adhesive. Examples of such a configuration are depicted in FIGS. 12A and 12B.

FIGS. 12A and 12B show examples of cross-sectional schematic illustrations of touchscreen configurations (350, 370) where bonding interfaces between the touch panel 365 and the cover plate 360 can each include a bulk diffuser layer 362 and a non-diffusive layer 364. In the example shown in FIG. 12A, the diffusive layer 362 is disposed rearward of the cover plate 360, followed by the non-diffusive layer 364. In the example shown in FIG. 12B, the non-diffusive layer 364 is disposed rearward of the cover plate 310, followed by the diffusive layer 362. The foregoing example configurations can be implemented in situations where it is desirable to have a limited thickness of a diffusive layer (such as 362 in FIGS. 12A and 12B) but a larger spacing between a cover plate (such as cover plate 360) and a touch panel to, for example, allow one or more electrical connections (e.g., flex printed circuit) to be attached to signal traces on the touch panel.

In the examples shown in FIGS. 12A and 12B, the touch panels 365 are depicted as having an insulator 368 and one conductive layer 366 disposed on the front side of the insulator 368. It will be understood, however, that touch panels can configured so that conductive layer(s) can be on either or both sides of the insulator layer 368. Additionally, a display device 352 can be coupled to the touch panel with or without a gap 354 (e.g., an air gap).

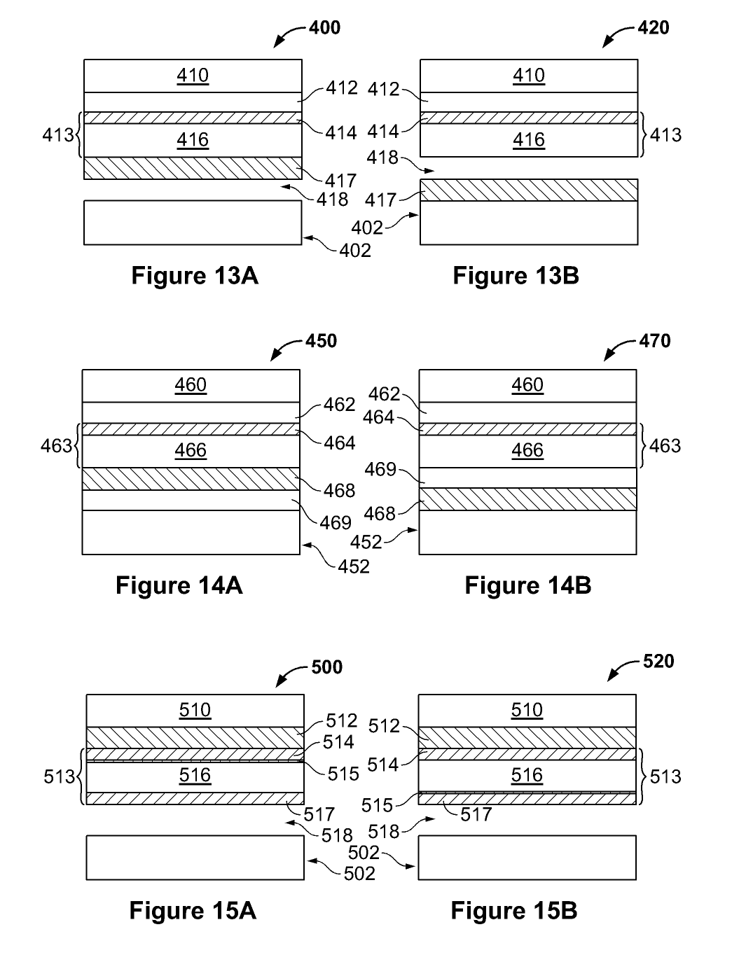

FIGS. 13A and 13B show examples of cross-sectional schematic illustrations of a touchscreen assembly having a front cover, a touch panel, a display device, and disposed between the touch panel and the display a bulk diffuser. FIGS. 13A and 13B show that in some implementations, a bulk diffuser can be positioned between a touch panel and a display device. For example, a touchscreen assembly 400 (as illustrated in the example of FIG. 13A) includes a touch panel 413 having a transparent insulator 416 and a transparent conductive layer 414 coupled to a cover panel 410 via a non-diffusive adhesive layer 412. A bulk diffuser 417 is depicted as being positioned rearward of the touch panel 413. FIG. 13A shows that in some implementations, the bulk diffuser 417 can be positioned directly rearward of the rear surface of the transparent insulator 416. The touchscreen configuration 400 further includes a display device 402 that is positioned rearward of the bulk diffuser 416 so as to define a gap (e.g., an air gap) between the bulk diffuser 416 and the display device 402.

In the example touchscreen configuration 420 of FIG. 13B, the bulk diffuser 416 is depicted as being positioned in front of the display device 402 (that is the bulk diffuser 416 is in front of the front surface of the display device 402, and on the same side of the gap 418 as the display device 402). The bulk diffuser 416 and the rear portion of the touch panel 413 are depicted as defining a gap (which in some implementations is an air gap) therebetween. In some implementations, the gaps 418 between the display device 402 and the touch panel 413 of FIGS. 13A and 13B can be filled with a transparent coupling medium such as a transparent adhesive.

FIGS. 14A and 14B show examples of cross-sectional schematic illustrations of a touchscreen assembly having a front cover, a touch panel, a display device, and disposed between the touch panel and the display a bulk diffuser and a transparent adhesive. In FIG. 14A, an example touchscreen configuration 450 can include a transparent coupling medium 469 such as a non-diffusive adhesive that can be provided so as to fill the gap 418 of FIG. 13A. Similarly, in FIG. 14B, an example touchscreen configuration 470 can include the transparent coupling medium 469 that can be provided so as to fill the gap 418 of FIG. 13B. Similar to the examples of FIGS. 13A and 13B, a bulk diffuser 468 can be provided directly rearward of the rear surface of a transparent insulator 466 or directly in front of the front surface of a display device 452.

Referring to FIGS. 14A and 14B, in some implementations, a cover plate 460, a transparent adhesive 462, a touch panel 463 having the transparent insulator 466 and a transparent conductive layer 464, and the display device 452 can be similar to those configurations 400, 420 described in reference to FIGS. 13A and 13B. Further, in the examples shown in FIGS. 13 and 14, the touch panels 413 and 464 are depicted as having the transparent insulator 416 or 466 and one conductive layer 414 or 464 on the front side of the transparent insulator 416 or 466. It will be understood, however, that touch panels can configured so that conductive layer(s) can be on either or both sides of the insulator layer 416 or 466.

As described herein in reference to FIGS. 11-14, a bulk diffusion layer can be configured with different compositions and/or thicknesses so as to provide, for example, different haze characteristics for different implementations. For example, a touchscreen assembly based on an interferometric modulator array can be provided with a haze level in a range of about 5 to about 50% to achieve a desired effect. In other touchscreen assemblies based on displays such as LCD, transmissive or emissive devices, a haze level can be higher, with an upper limit of haze level in a range of about 65 to 70%. For the purpose of description herein, a haze level can include a meaning of a percentage of light scattered (out of straight ahead direction) when passing through a given material.

Further, a diffusive layer's distance from a display plane can affect the quality of an image displayed on the plane. For example, when a diffusive layer is positioned farther away from a display, less haze may be needed to achieve a desired effect. Thus, as described herein in reference to FIGS. 11-14, a bulk diffusion layer can be positioned at different locations relative to, for example, a display device.

In some implementations, more than one bulk diffusion layer can be provided at different locations in a touchscreen structure. For example, a touch sensor may be configured to include a plurality of layers of plastic film with an adhesive bonding layer having a bulk diffusion property at each of the plastic film layers. Among such bulk diffusion layers, the diffusion layers farther away from the display can be configured to have less haze than those closer to the display.

FIGS. 15A and 15B show examples of cross-sectional schematic illustrations of a touchscreen assembly having a number of interface surfaces behind the front surface of a front cover, where one or more of such interface surfaces can be configured as a diffusive surface having a desired diffusion property. In particular, FIGS. 15A and 15B show that in some implementations, one or more diffusive surfaces (such as a textured surface) can be provided in a touchscreen assembly. In the examples shown, the diffusive surfaces can be provided in combination with bulk diffusers. In some implementations, however, one or more features associated with such diffusive surfaces can be implemented without a bulk diffuser.

In FIGS. 15A and 15B, each of example touchscreen assemblies 500, 520 is shown to include a bulk diffuser 512 disposes between a cover plate 510 and a touch panel 513 having a transparent insulator 516 and transparent conductive layers 514, 517 formed on both sides of the transparent insulator 516. The touch panel 513 is further shown to be disposed relative to a display panel 502 so as to form an air gap 518 therebetween.

In the first example configuration 500, a diffusive surface 515 is provided between the transparent conductive layer 514 and the front portion of the insulator layer 516. In the second example configuration 520, a diffusive surface 515 is provided between the transparent conductive layer 517 and the rear portion of the insulator layer 516.

In some implementations, the diffusive surface 515 can be configured so as to yield an effective index difference between the diffusive surface and a medium next to the surface. For example, the medium can be air, bonding material, or transparent conductor (e.g., ITO layer); and such a medium can have an index of n₁. In some implementations, the diffusive surface 515 can be configured so as to have an effective index of n₂ such that the difference between n₁ and n₂ is greater than or equal to about +/−0.01. In some implementations, a diffusive surface (e.g., the diffusive surface 515) can be formed in a number of ways, including, for example, roughening of a surface of a medium.

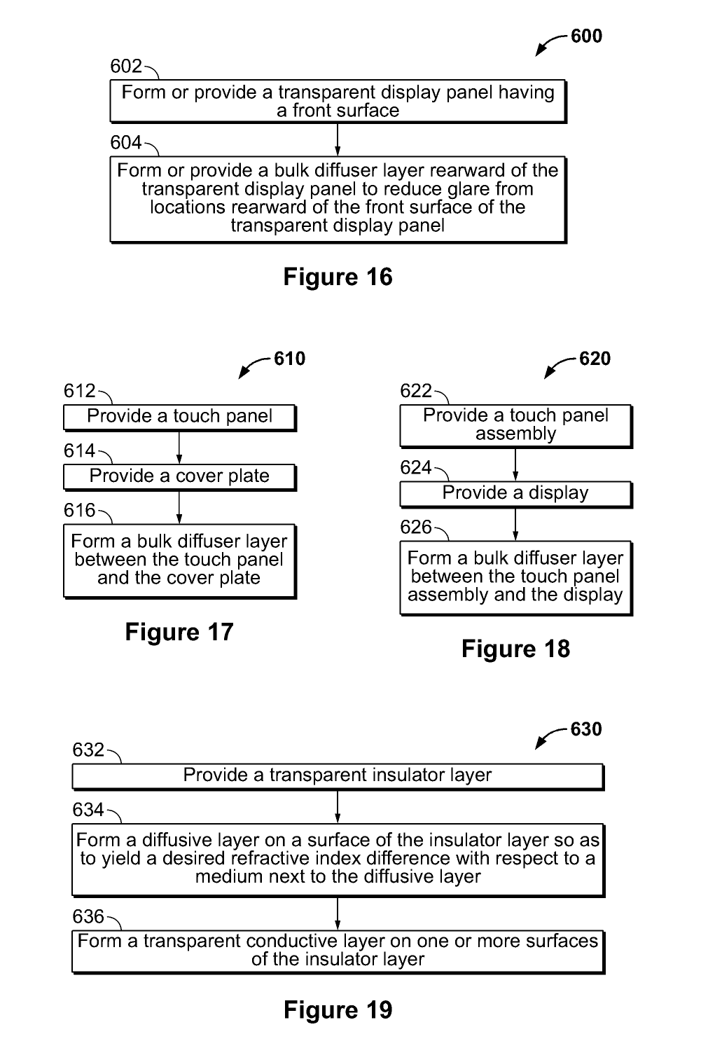

FIG. 16 shows a process 600 that can be implemented to fabricate a display device having a bulk diffuser for reducing glare from one or more surfaces behind the front surface of a touchscreen device. In block 602, a display can be provided. In block 604, a touch sensor can be provided so as to be positioned in front of the display. In block 606, a cover layer can be provided so as to be positioned in front of the touch sensor such that a front surface of the cover layer defines the front surface of the touchscreen device. In block 608, a bulk diffuser layer can be formed or provided at a location rearward of the cover layer so as to reduce glare from one or more internal surfaces rearward of the front surface of the touchscreen device.

In process 600, the one or more internal surfaces can include surfaces that are rearward of the front surface of the cover layer. In situations where a touchscreen device does not have a cover layer, or where the front-most layer is a layer that provides a function other than a cover functionality, it will be understood that the one or more internal surfaces can include surfaces that are rearward of the front-most surface of the touchscreen device.

FIG. 17 shows a process 610 that can be implemented to fabricate a touchscreen device having a bulk diffuser for reducing glare from one or more surfaces behind the front surface of a cover plate. In block 612, a touch panel can be provided. Various examples of such a touch panel are described herein. In block 614, a cover plate can be provided. In block 616, a bulk diffuser layer can be formed or provided between the touch panel and the cover plate so as to reduce glare from locations rearward of the cover plate of the touchscreen device.

FIG. 18 shows a process 620 that can be implemented to fabricate a touchscreen display device having a bulk diffuser for reducing glare from one or more surfaces behind the front surface of a cover plate of the touchscreen. In block 622, a touch panel assembly can be provided. In block 624, a display device can be provided. In block 626, a bulk diffuser layer can be formed or provided between the touch panel assembly and the display device.

FIG. 19 shows a process 630 that can be implemented to fabricate a touchscreen device having one or more diffusive surfaces. In block 632, a transparent insulator layer can be formed or provided. In block 634, a diffusive surface can be formed on a surface of the insulator layer so as to yield a desired effective refractive index that is different than the index of a medium next to the diffusive surface. In some implementations, the medium can be a transparent conductive layer such as an ITO layer. Other media (such as air) are also possible. In block 636, a transparent conductive layer can be formed on the diffusive surface of the transparent insulator.

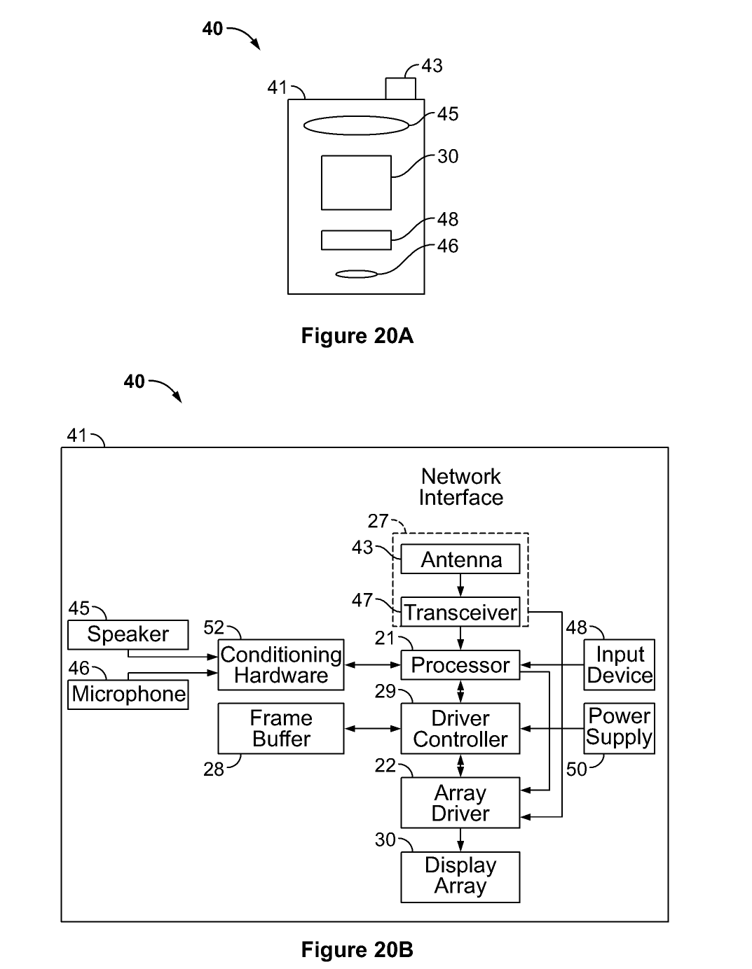

FIGS. 20A and 20B show examples of system block diagrams illustrating a display device 40 that includes a plurality of interferometric modulators. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 20B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blue-ray disc where disks usually reproduce data magnetically, while discs reproduce data optically with lasers. Combinations of the above also may be included within the scope of computer-readable media. Additionally, the operations of a method or algorithm may reside as one or any combination or set of codes and instructions on a machine readable medium and computer-readable medium, which may be incorporated into a computer program product. Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other possibilities or implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of an IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A display apparatus, comprising:
a front cover;
a touch panel disposed rearward of the front cover and having front and rear surfaces;
a display array rearward of the touch panel; and
at least one diffuser disposed rearward of the front cover so as to reduce glare resulting from substantially specular reflection from at least one of the front and rear surfaces of the touch panel.

2. The apparatus of claim 1, wherein the diffuser includes a layer of diffusive adhesive.

3. The apparatus of claim 1, wherein the at least one diffuser includes
a first diffuser layer disposed between the front cover and the touch panel; and
a second diffuser layer disposed between the touch panel and the display array.

4. The apparatus of claim 1, further comprising a transparent adhesive disposed between the front cover and the touch panel.

5. The apparatus of claim 1, wherein the display array includes an interferometric modulator array.

6. The apparatus of claim 1, wherein at least one of the surfaces of the touch panel includes a diffusive surface.

7. The apparatus of claim 6, wherein the touch panel diffusive surface includes a roughened surface having an effective refractive index, and wherein the refractive index difference between the roughened surface and a medium disposed next to the diffusive surface is greater than or equal to about 0.01.

8. The apparatus of claim 7, wherein the medium is air.

9. The apparatus of claim 7, wherein the medium is a bonding material.

10. The apparatus of claim 7, wherein the medium is ITO.

11. The apparatus of claim 1, wherein the at least one diffuser includes a plurality of layers, each layer having a haze characteristic that decreases as a function of the layer's distance from the display array.

12. The apparatus of claim 1, further comprising:
a processor that is configured to communicate with the display array, the processor being configured to process image data; and
a memory device that is configured to communicate with the processor.

13. The apparatus of claim 12, further comprising:
a driver circuit configured to send at least one signal to the display array; and
a controller configured to send at least a portion of the image data to the driver circuit.

14. The apparatus of claim 13, further comprising:
an image source module configured to send the image data to the processor, wherein the image source module includes at least one of a receiver, transceiver, and transmitter.

15. The apparatus of claim 1, further comprising an input device coupled to the touch panel and configured to receive input data and to communicate the input data to the processor.

16. A touchscreen device having an external surface, the touchscreen device comprising:
a display;
a touch sensor; and
at least one bulk diffuser disposed relative to the touch sensor so as to reduce glare from one or more internal surfaces of the touchscreen device.

17. The device of claim 16, further comprising a cover plate disposed such that the touch sensor is between the cover plate and the display, one surface of the cover plate defining the external surface of the touchscreen device.

18. The device of claim 16, wherein the at least one bulk diffuser is disposed between the cover plate and the touch sensor is disposed between the touch sensor and the display.

19. A method for fabricating a display, the method comprising:
providing a display array;
providing a touch panel having front and rear surfaces in front of the display array;
forming at least one bulk diffuser at one or more sides of the front and rear surfaces of the touch panel; and
disposing a front cover in front of the touch panel.

20. The method of claim 19, wherein the at least one bulk diffuser is formed so as to be in direct contact with the front surface of the touch panel or in direct contact with the rear surface of the touch panel.

21. The method of claim 19, further comprising forming at least one non-diffusive layer at one or more sides of the front and rear surfaces of the touch panel.

22. The method of claim 21, wherein the at least one non-diffusive layer is an adhesive layer formed so as to be positioned between the front or rear surface of the touch panel and the at least one bulk diffuser.

23. A method for fabricating a touchscreen device, the method comprising:
providing a display;
providing a touch sensor;
providing a cover plate disposed such that the touch sensor is between the cover plate and the display; and
forming at least one diffuser between the cover plate and the display so as to reduce glare from one or more internal surfaces of the touchscreen device.

24. An apparatus comprising:
a display device configured to display an image by providing signals to selected locations of the display device;
a touch panel configured to receive user inputs;
a front cover configured to protect the touch panel; and
means for reducing glare resulting from specular reflection from at least one surface below the front cover.
